(19) United States
(12) Patent Application Publication
(10) Pub. No.: US 2026/0271384 A1
(43) Pub. Date: Sep. 10, 2026

(54) SEMICONDUCTOR STRUCTURE AND METHOD FOR FORMING THE SAME

(71) Applicant: TAIWAN SEMICONDUCTOR MANUFACTURING COMPANY LTD., HSINCHU (TW)

(72) Inventors: YUAN TSUNG TSAI, TAINAN CITY (TW); YING MING WANG, TAINAN CITY (TW); HUEI TANG WANG, TAOYUAN CITY (TW); WEI CHE TSAI, PINGTUNG CITY (TW); CHIA-HUI SHEN, YUNLIN COUNTY (TW); SUNG-HSIN YANG, TAINAN (TW)

(21) Appl. No.: 19/073,064

(22) Filed: Mar. 7, 2025

(51) Int. Cl. H10D 84/83; H10D 30/01; H10D 30/62; H10D 62/10; H10D 84/01

(52) U.S. Cl. CPC H10D 84/834; H10D 30/024; H10D 30/6211; H10D 30/6212; H10D 62/115; H10D 84/0158; H10D 62/102

(57) ABSTRACT

A semiconductor structure includes a substrate, a first semiconductor fin, a shark-fin-shaped semiconductor structure, a second semiconductor fin, an isolation feature, and a gate structure. The isolation feature is disposed over the substrate and between the first semiconductor fin and the second semiconductor fin, and is adjacent to a sidewall of the first semiconductor fin. The gate structure extends over the isolation feature, the first semiconductor fin, the shark-fin-shaped semiconductor structure, and the second semiconductor fin, and interfaces a top surface of the isolation feature. The shark-fin-shaped semiconductor structure has a first sidewall and a second sidewall connected to the first sidewall at a point.

### BACKGROUND

The electronics industry is experienced an ever-increasing demand for smaller and faster electronic devices that are able to support greater numbers of increasingly complex and sophisticated functions. Accordingly, there is a continuing trend in the semiconductor industry to manufacture low-cost, high-performance, low-power integrated circuits (ICs). Thus far, such goals have been achieved in large part by scaling down semiconductor IC dimensions (e.g., minimum feature size) and thereby improving production efficiency and reducing associated costs. However, such downscaling has also introduced increased complexity to the semiconductor manufacturing process. Thus, the realization of continued advances in semiconductor ICs and devices requires similar advances in semiconductor manufacturing processes and technology.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a perspective view illustrating a semiconductor structure according to some embodiments of the present disclosure.

FIGS. 2A to 2R are schematic drawings illustrating the semiconductor structure at various fabrication stages according to some embodiments of the present disclosure.

FIGS. 3A and 3B are cross-sectional views illustrating the semiconductor structure at a fabrication stage of FIG. 2K according to some embodiments of the present disclosure.

FIG. 4 is a top view illustrating the semiconductor structure according to some embodiments of the present disclosure.

FIG. 5 is a cross-sectional view illustrating a semiconductor structure according to some other embodiments of the present disclosure.

FIG. 6 is a flowchart representing a method for forming a semiconductor structure according to some embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first,” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” or “about” generally mean within a value or range that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

The fins may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins.

The present disclosure is applicable to semiconductor structures, in particular to fin field-effect transistors (FinFETs). During manufacturing a semiconductor structure, some unnecessary semiconductor fins may be removed. The removal of these semiconductor fins may make the stress on the remaining semiconductor fins uneven, which causes the remaining semiconductor fins to incline. The inclined semiconductor fins may narrow the filling window of the sequentially-formed metal gate, resulting in high threshold voltage (Vt) inducing low voltage fail.

Embodiments of semiconductor structure and a method for forming a semiconductor structure are therefore provided. In some embodiments, the method includes uneven removal of the unnecessary semiconductor fins, thereby forming a shark-fin-shaped structure, which can balance the stress on the remaining semiconductor fins. As a result, the issues with poor metal gate filling can be addressed.

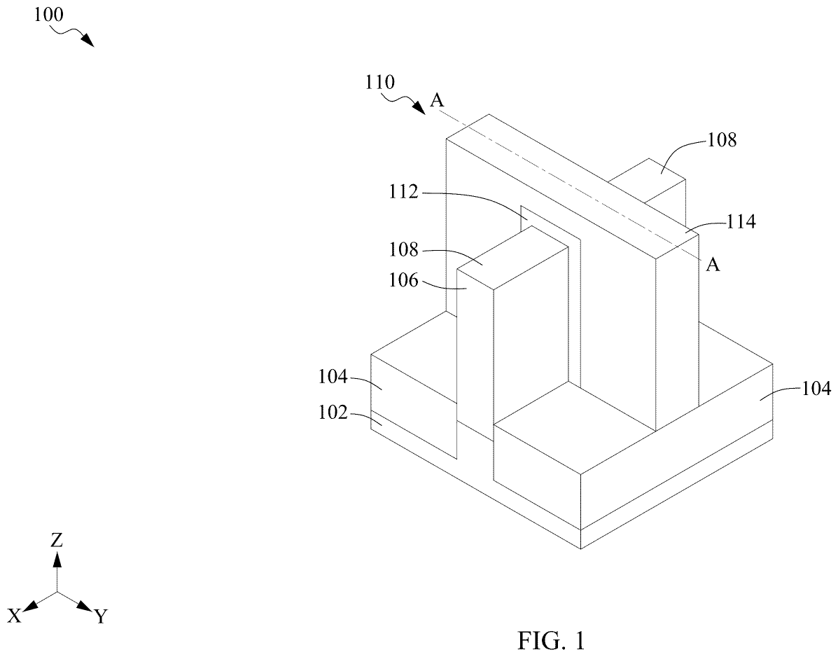

FIG. 1 is a perspective view illustrating a semiconductor structure 100 according to some embodiments of the present disclosure. The semiconductor structure 100 may be a FinFET. The semiconductor structure 100 may include isolation features 104 in a substrate 102. The semiconductor structure 100 may include a semiconductor fin 106 protruding above and from between neighboring isolation features 104. A gate structure 110 may include a gate dielectric 112 along sidewalls and over a top surface of the semiconductor fin 106, and a gate electrode 114 over the gate dielectric 112. Portions of the semiconductor fin 106 covered by the gate structure 110 may serve as a channel region. Source/drain features 108 may be disposed in opposite sides of the semiconductor fin 106 with respect to the gate structure 110. Source/drain region(s) may refer to a source or a drain, individually or collectively dependent upon the context.

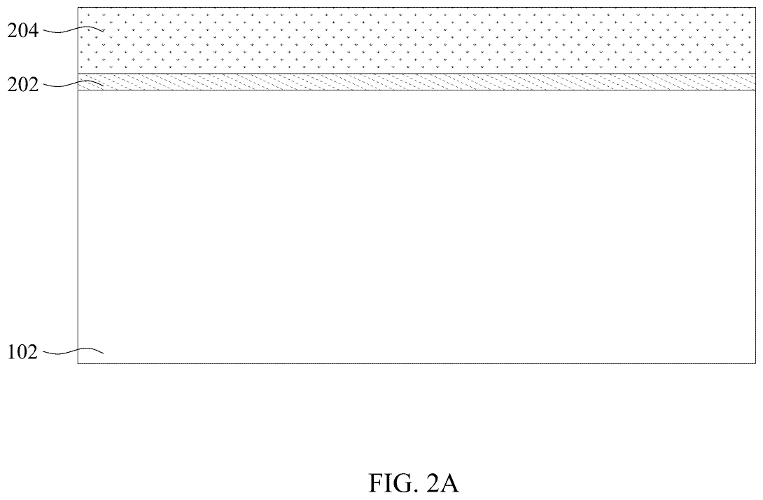

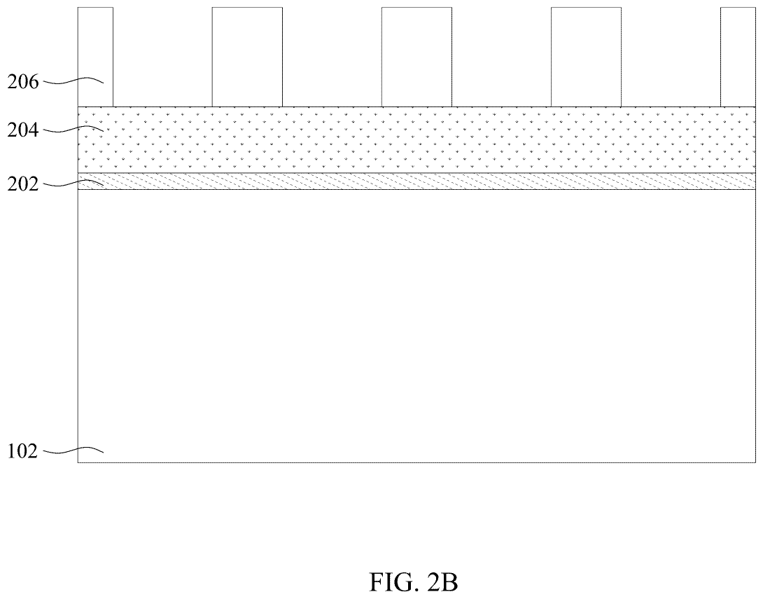

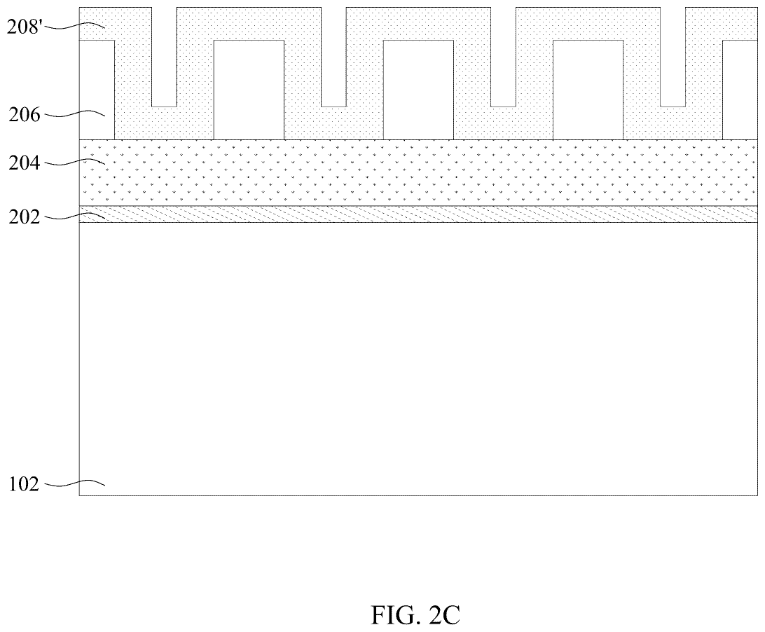

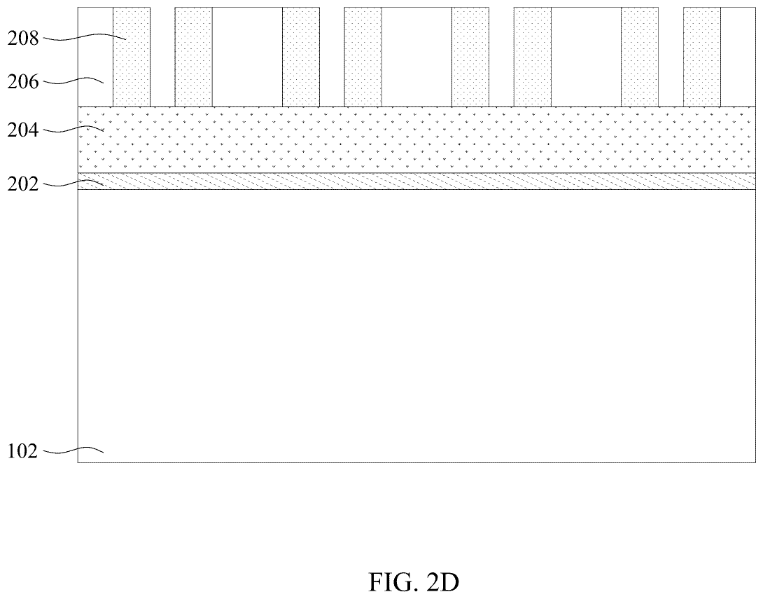

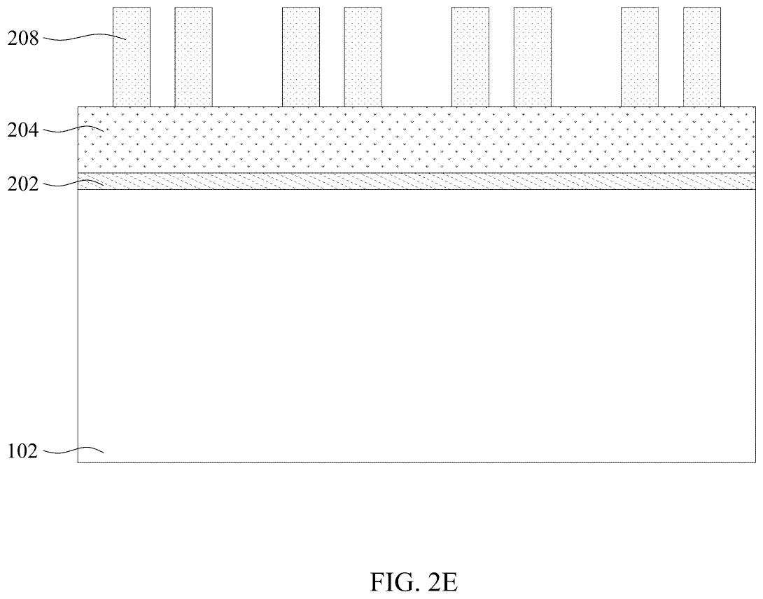

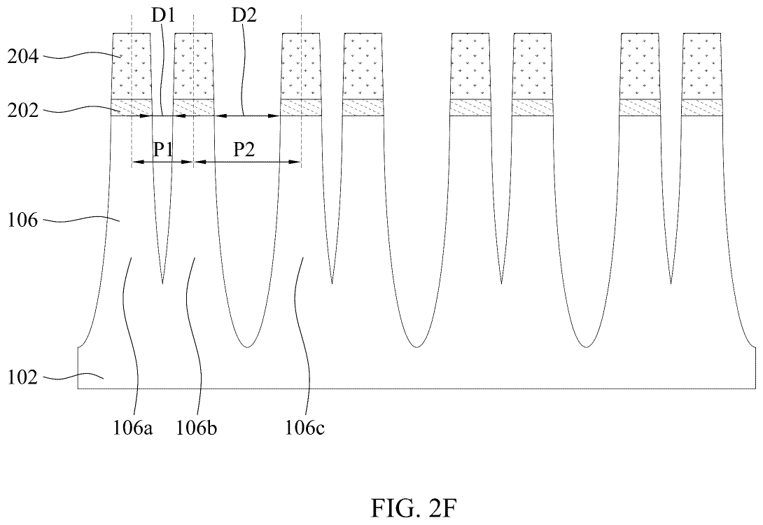

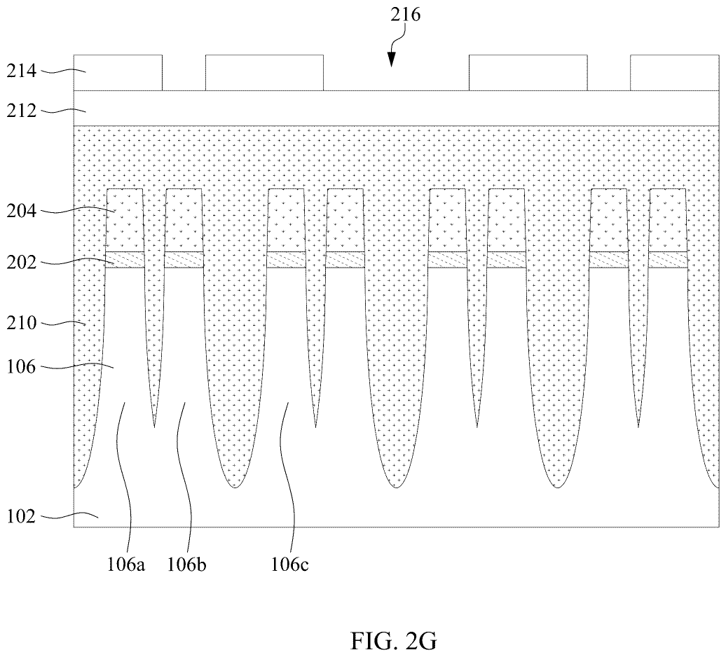

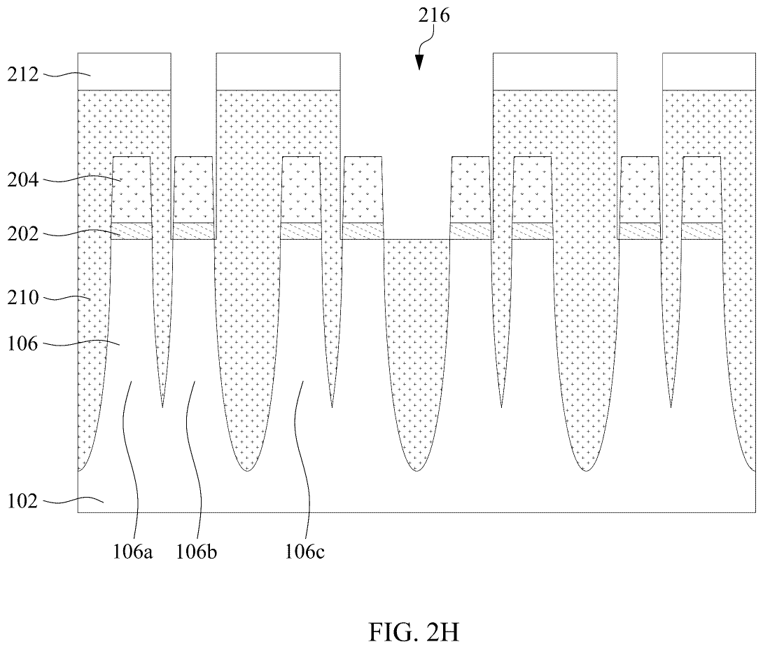

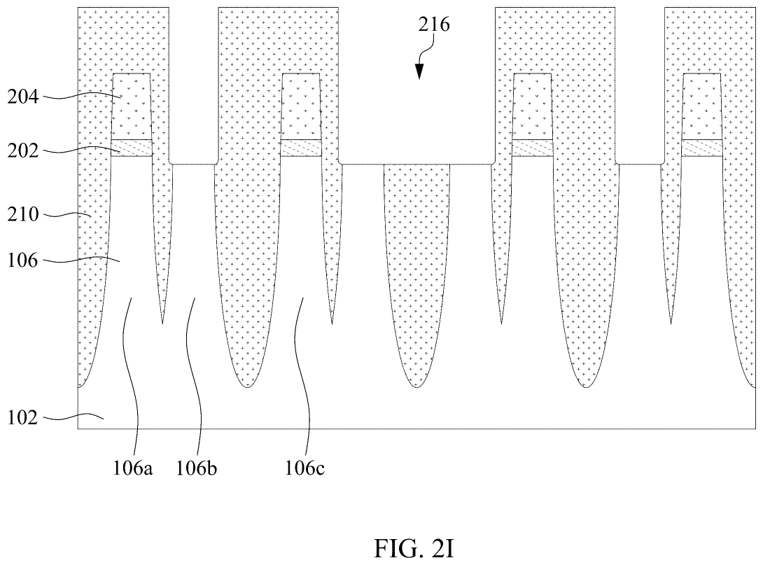

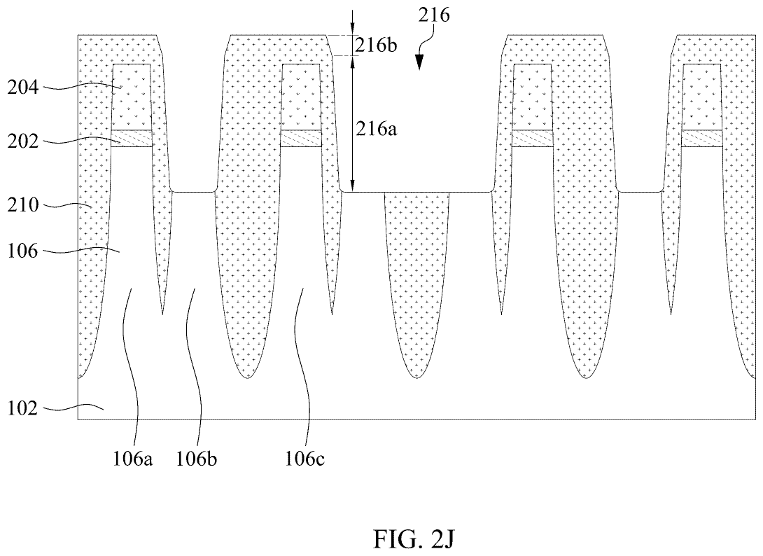

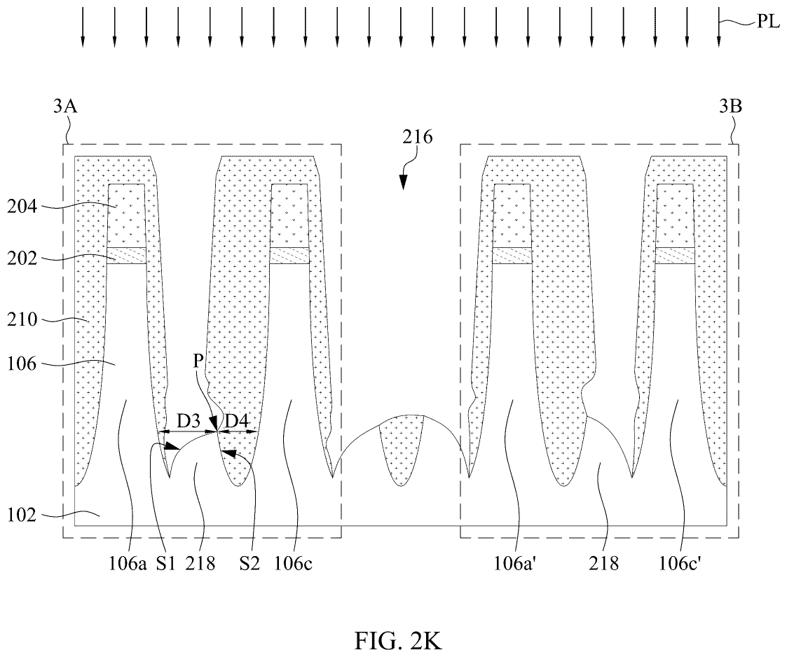

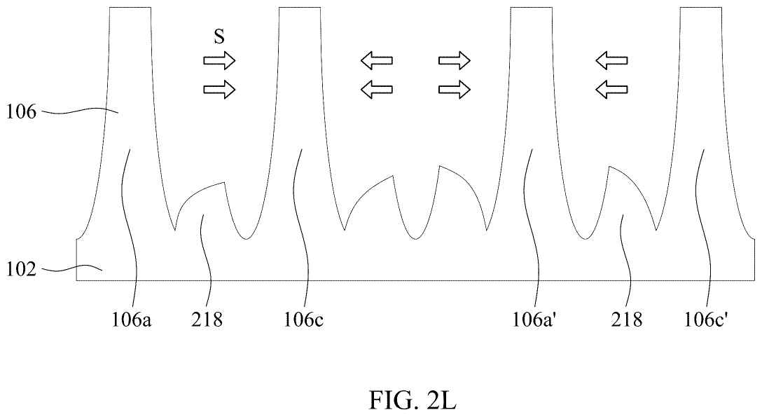

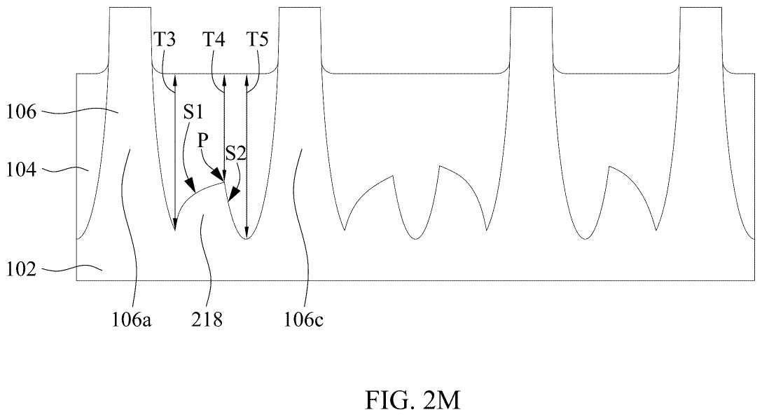

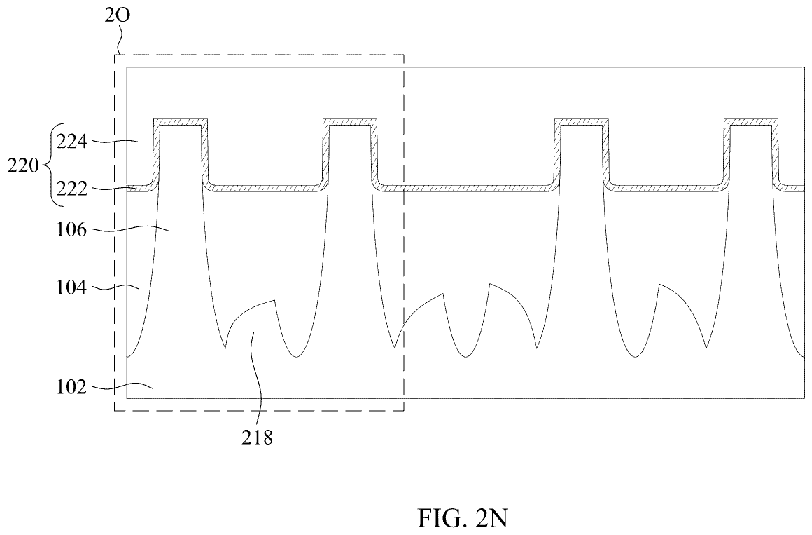

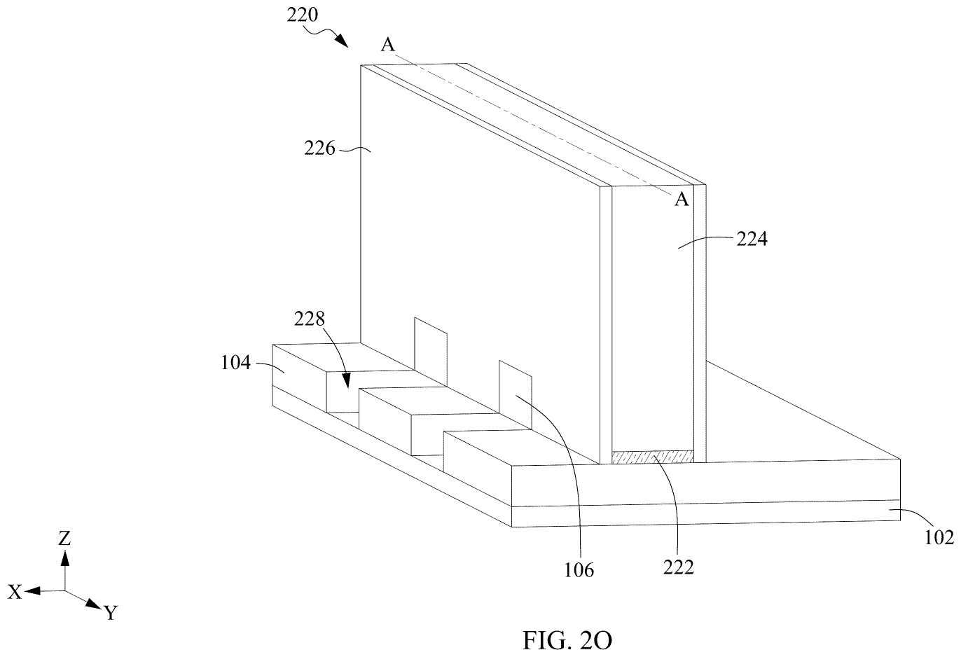

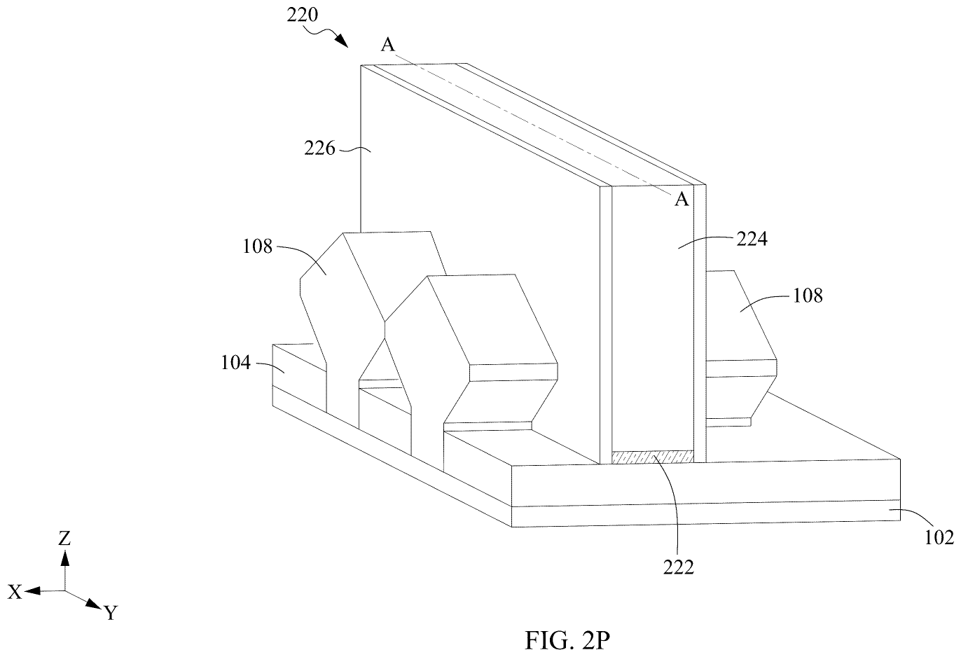

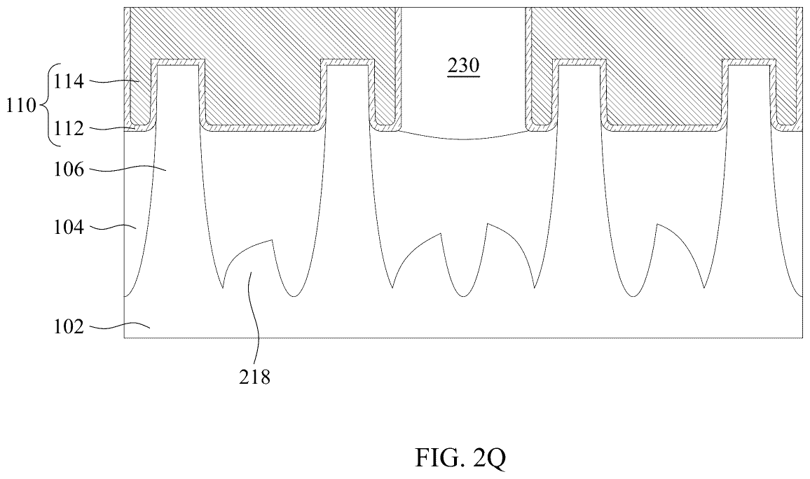

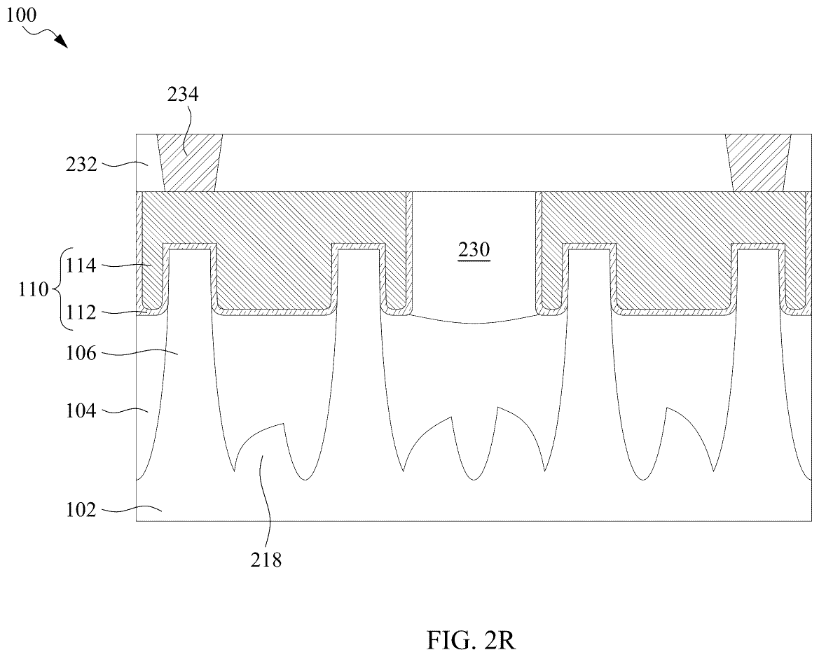

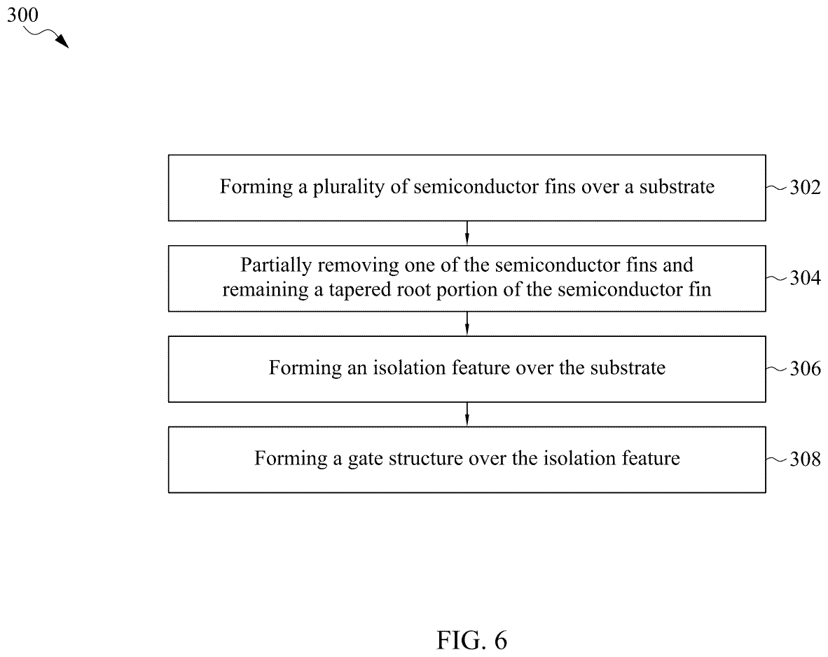

FIGS. 2A to 2R are schematic drawings illustrating the semiconductor structure 100 at various fabrication stages according to some embodiments of the present disclosure. FIGS. 2A to 2N, 2Q and 2R are cross-sectional views of an YZ plane along the A-A line in FIG. 1, which is across a channel region and the gate structure 110 of the semiconductor structure 100. FIGS. 2O and 2P are perspective view illustrating the semiconductor structure 100 at fabrication stages between the fabrication stages of FIGS. 2N and 2Q. The corresponding operations are also reflected schematically in a flowchart in FIG. 6 according to some embodiments.

FIG. 6 is a flowchart representing a method 300 for forming the semiconductor structure 100 according to some embodiments of the present disclosure. The method 300 includes a number of operations (302, 304, 306, and 308). The method 300 will be further described according to one or more embodiments. It should be noted that the operations of the method 300 may be rearranged or otherwise modified within the scope of the various aspects. It should be further noted that additional processes may be provided before, during, and after the method 300, and that some other processes may just be briefly described herein. Thus, other implementations are possible within the scope of the various aspects described herein.

Referring to FIG. 2A, a substrate 102 is provided, according to some embodiments. The substrate 102 may be a semiconductor substrate such as a silicon substrate. The substrate 102 may also include other semiconductors such as germanium (Ge), silicon carbide (SiC), silicon germanium (SiGe), or diamond. Alternatively, the substrate 102 may include a compound semiconductor and/or an alloy semiconductor. The substrate 102 may include various layers, including conductive or insulating layers formed on a semiconductor substrate. The substrate 102 may include various doping configurations depending on design requirements. For example, different doping profiles (e.g., n wells or p wells) may be formed on the substrate 102 in regions designed for different device types (e.g., n-type field-effect transistors (NFET), or p-type field-effect transistors (PFET)). The suitable doping may include ion implantation of dopants and/or diffusion processes.

Then, a pad layer 202 and a hard mask layer 204 are sequentially formed over the substrate 102, according to some embodiments. In some embodiments, the pad layer 202 include a silicon oxide layer formed, for example, by thermal oxidation process. The pad layer 202 may act as an adhesion layer between the substrate 102 and the hard mask layer 204 and may act as an etch supper layer for etching the hard mask layer 204. In some embodiments, the hard mask layer 204 include a silicon nitride layer formed, for example, by low-pressure chemical vapor deposition (LPCVD) or plasma enhanced chemical vapor deposition (PECVD).

Subsequently, referring to FIG. 2B, a plurality of mandrels 206 are formed over the hard mask layer 204, according to some embodiments. The mandrels 206 serve as temporary support structures for the formation of sequentially formed spacers on sidewalls of each of the mandrels 206. In some embodiments, the mandrels 206 are formed by depositing, patterning, and etching a semiconductor layer, including poly-Si, Ge, SiGe, or another suitable material. The depositing may be performed by chemical vapor deposition (CVD), oxidation, physical vapor deposition (PVD), atomic layer deposition (ALD), or another suitable technique. The patterning may be performed by a photolithography processes, which may include photoresist coating (e.g., spin-on coating), soft baking, mask aligning, exposure, post-exposure baking, developing the photoresist, rinsing, drying (e.g., hard baking), another suitable processes, or a combination thereof. The etching may be performed by dry etch, plasma etch, reactive ion etching, ion beam etching, or another suitable technique.

Then, referring to FIG. 2C, a spacer layer 208′ is formed over and along sidewalls of the mandrels 206, according to some embodiments. The spacer layer 208′ may extend along top surfaces of the hard mask layer 204 which are exposed by the mandrels 206. The spacer layer 208′ may include a dielectric material such as silicon oxide (SiO₂), silicon nitride (Si₃N₄), silicon oxynitride (SiON), a high-K dielectric material, silicon carbide, or a combination thereof. Materials used for the mandrels 206 and the spacer layer 208′ may be selected such that there is an etch selectivity between the mandrels 206 and the spacer layer 208′.

Afterwards, referring to FIG. 2D, the dielectric material of the spacer layer 208′ is etched to remove lateral portions of the spacer layer 208′ while leaving a plurality of spacers 208 on sidewalls of the mandrels 206, according to some embodiments. Etching the spacer layer 208′ may expose the mandrels 206 and portions of the hard mask layer 204 between the spacers 208. Etching the spacer layer 208′ may include a dry etch process, and may be anisotropic. The dry etch process may selectively etch the spacer layer 208′ at a higher rate than the mandrels 206, such as using etchants including CF₄, NF₃, HCl, HBr, or the like.

Then, referring to FIG. 2E, the mandrels 206 are selectively removed using an etching process, leaving the spacers 208, according to some embodiments. The etching process may include a wet etch process, a dry etching process, or a combination thereof. Exemplary wet etch process may include a standard clean 1 (SC-1) including ammonium hydroxide (NH₄OH), hydrogen peroxide (H₂O₂), and water (H₂O). Exemplary dry etch process may include plasma etching, reactive ion etching (RIE), ion beam etching, or another suitable techniques. The spacers 208 may serve as an etch mask, and the pattern defined by the spacers 208 may be transferred to the underlying layers.

Afterwards, referring to FIG. 2F, the hard mask layer 204, the pad layer 202, and the substrate 102 are sequentially etched by anisotropic etching processes, according to some embodiments. Anisotropic etching processes may include plasma etching, reactive ion etching, ion beam etching, or another suitable techniques. These etches may be performed in-situ or in separate etching processes. For example, the etching of the hard mask layer 204, the pad layer 202, and the substrate 102 may occur in the same processing chamber without intervening processes. Next, the spacers 208 may be selectively removed by a wet etch process, a dry etching process, or a combination thereof. Thus, a plurality of semiconductor fins 106 are formed. The respective process is illustrated as operation 302 in the method 300 as shown in FIG. 6.

The widths of the semiconductor fins 106 may be substantially the same. The semiconductor fins 106 may have the same or different pitches. For example, the pitch P1 between the semiconductor fin 106a and the semiconductor fin 106b may be different from the pitch P2 between the semiconductor fin 106b and the semiconductor fin 106c. In particular, the pitch P1 between the semiconductor fin 106a and the semiconductor fin 106b may be less than the pitch P2 between the semiconductor fin 106b and the semiconductor fin 106c. The distance D1 between the semiconductor fin 106a and the semiconductor fin 106b may be less than the distance D2 between the semiconductor fin 106b and the semiconductor fin 106c. In some embodiments, the various pitches are formed according to product or process design. In some alternative embodiments, the various pitches are unintentionally formed. The etching process on different regions of the substrate 102 may vary accordingly. As a result, the top surfaces of the substrate 102 between adjacent semiconductor fins 106 may have height difference after forming the semiconductor fins 106. For example, the top surface of the substrate 102 between the semiconductor fin 106a and the semiconductor fin 106b may be higher than the top surface of the substrate 102 between the semiconductor fin 106b and the semiconductor fin 106c.

Then, referring to FIG. 2G, a mask layer is formed over the substrate 102, according to some embodiments. The mask layer may include a bottom layer 210 covering the hard mask layer 204, the pad layer 202, the semiconductor fins 106, and the substrate 102, a middle layer 212 over the bottom layer 210, and an upper layer 214 over the middle layer 212. The bottom layer 210 may be a bottom anti-reflective coating (BARC) layer. The middle layer 212 may include inorganic material, including a nitride (such as silicon nitride), an oxynitride (such as silicon oxynitride), or the like. The upper layer 214 may be formed of photoresists such as photosensitive materials, which may include organic materials. The bottom layer 210, the middle layer 212, and the upper layer 214 may be deposited using, for example, spin-on process.

Although the tri-layer mask layer is discussed herein, the mask layer may be a monolayer or a bilayer mask layer in some other embodiments, such as includes the bottom layer 210 and the upper layer 214 without the middle layer 212. The type of the mask layer adopted may depend on the photolithography process used. For example, in some embodiments using extreme ultraviolet (EUV) lithography, a monolayer or bilayer mask layer may be adopted.

Subsequently, still referring to FIG. 2G, the upper layer 214 is patterned using a photolithography process to form openings 216, according to some embodiments. For example, a photomask (not illustrated) may be disposed over the upper layer 214, and the upper layer 214 may be exposed to a radiation beam such as an ultraviolet (UV) while the photomask masks some areas of the upper layer 214. A bake or cure operation may be performed to harden the upper layer 214, and a developer may be used to remove either the exposed or unexposed portions of the upper layer 214 depending on whether a positive or negative resist is used. The upper layer 214 may serve as an etching mask for patterning the middle layer 212, and the middle layer 212 may then serve as an etching mask for patterning the bottom layer 210.

After patterning the upper layer 214, the pattern of the upper layer 214 may be transferred to the middle layer 212 in an etching process, thereby extending the opening 216 through the middle layer 212. Then, the pattern may be further transferred to the bottom layer 210 in an etching process, thereby extending the opening 216 into the bottom layer 210, as illustrated in FIG. 2H. The etching processes may be anisotropic. In some embodiments, the upper layer 214 may be consumed during etching the bottom layer 210. In other embodiments, the upper layer 214 may be removed after transferring the opening 216 into the bottom layer 210. The opening 216 may expose some of the pad layer 202 and the hard mask layer 204, such as the pad layer 202 and the hard mask layer 204 over the semiconductor fin 106b.

Subsequently, referring to FIG. 2I, the exposed pad layer 202 and the exposed hard mask layer 204 are removed from the opening 216, according to some embodiments. Removal of the exposed pad layer 202 and the exposed hard mask layer 204 may be performed by using any suitable etching process, including a wet etch process, a dry etching process, or a combination thereof. During the removal of the exposed pad layer 202 and the exposed hard mask layer 204, the bottom layer 210 and top portions of the semiconductor fins 106 below the exposed pad layer 202 and the exposed hard mask layer 204 (such as the semiconductor fin 106b) may also be partially removed, thereby slightly widening the opening 216. After the removal of the exposed pad layer 202 and the exposed hard mask layer 204, some of the semiconductor fins 106b may be exposed, which may be referred to as the exposed semiconductor fins 106b. In addition, the opening 216 may have rounded bottom corners.

Then, referring to FIG. 2J, the top portions of the exposed semiconductor fins 106b are removed by using any suitable etching process, according to some embodiments. The bottom layer 210 may also be partially removed, and the opening 216 may be widened. The opening 216 may have a lower tapered portion 216a and an upper tapered portion 216b over the lower tapered portion 216a. The upper tapered portion 216b may be wider than the lower tapered portion 216a. The width of the upper tapered portion 216b may decrease toward the substrate 102. The width of the lower tapered portion 216a may decrease toward the substrate 102. In particular, a minimum width of the upper tapered portion 216b may be substantially equal to a maximum width of the lower tapered portion 216a.

Subsequently, referring to FIG. 2K, portions of the exposed semiconductor fins 106b are removed with a soft de-corner step, according to some embodiments. A portion of the exposed semiconductor fins 106b may be remained and referred to as a tapered root portion 218. The respective process is illustrated as operation 304 in the method 300 as shown in FIG. 6. The soft de-corner step may use a high power plasma PL. The plasma PL may include a transformer coupled plasma (TCP) or another suitable technique. This approach has the capability to correct even-odd phenomena and can prevent the occurrence of small fin side effects while enlarging the overlay window. The space required for plasma etching of semiconductor fins 106 can thus be reduced. Therefore, the plasma PL may be applied without trimming the bottom layer 210 in advance.

The plasma PL may isotropic etch the exposed semiconductor fins 106b to meet the depth target. The exposed semiconductor fins 106b may be unevenly removed. In some embodiments, the plasma PL removes portions of the exposed semiconductor fins 106b more at smaller pitches. As a result, the tapered root portions 218 may have a shark-fin shape, and may also be referred to as shark-fin-shaped semiconductor structures 218. In particular, each of the shark-fin-shaped semiconductor structures 218 has a first sidewall S1 and a second sidewall S2 which are connect at a point P. The first sidewall S1 of the shark-fin-shaped semiconductor structure 218 may be convex and may extend from a bottom portion of the first semiconductor fin 106a toward a middle portion of the third semiconductor fin 106c. The second sidewall S2 of the shark-fin-shaped semiconductor structure 218 may be concave or substantially straight.

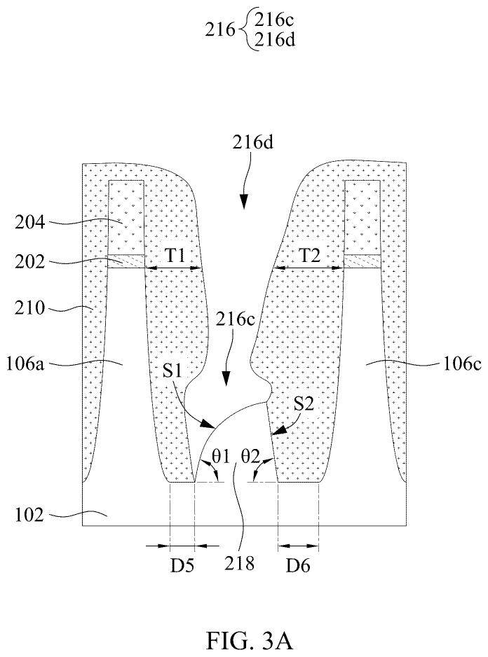

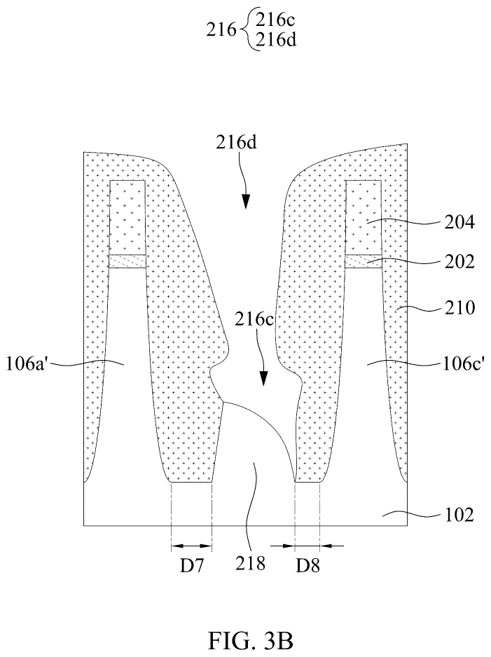

The structure of FIG. 2K is further described with reference to FIGS. 3A and 3B, as indicated by dashed blocks 3A and 3B in FIG. 2K, respectively. Referring to FIG. 3A, an included angle θ1 between the first sidewall S1 of the shark-fin-shaped semiconductor structure 218 and the substrate 102 may be different from an included angle θ2 between the second sidewall S2 of the shark-fin-shaped semiconductor structure 218 and the substrate 102. For example, the included angle θ1 between the first sidewall S1 of the shark-fin-shaped semiconductor structure 218 and the substrate 102 may be greater than the included angle θ2 between the second sidewall S2 of the shark-fin-shaped semiconductor structure 218 and the substrate 102.

A distance D5 between the bottom portion of the shark-fin-shaped semiconductor structure 218 and the semiconductor fin 106a is less than a distance D6 between the bottom portion of the shark-fin-shaped semiconductor structure 218 and the semiconductor fin 106c, according to some embodiments. The plasma may extend the opening 216 more at smaller pitches. In particular, the opening 216 may be deeper between the shark-fin-shaped semiconductor structure 218 and the semiconductor fin 106a than between the shark-fin-shaped semiconductor structure 218 and the semiconductor fin 106c.

The opening 216 may have a lower tapered portion 216c and an upper tapered portion 216d over the lower tapered portion 216c. The lower tapered portion 216c may be between the shark-fin-shaped semiconductor structure 218 and the semiconductor fin 106a. The upper tapered portion 216d may be between the semiconductor fin 106a and the semiconductor fin 106c. The width of the upper tapered portion 216d may decrease toward the substrate 102. The width of the lower tapered portion 216c may decrease toward the substrate 102. In some embodiments, a minimum width of the upper tapered portion 216d may be less than a maximum width of the lower tapered portion 216c.

Since the trimming process on the bottom layer 210 is omitted, the bottom layer 210 may have sufficient thickness on the sidewalls of the semiconductor fin 106a and the semiconductor fin 106c, such as the thickness T1 on the sidewall of the semiconductor fin 106a and the thickness T2 on the sidewall of the semiconductor fin 106c. Each of the thickness T1 on the sidewall of the semiconductor fin 106a and the thickness T2 on the sidewall of the semiconductor fin 106c may be greater than the thickness of the bottom layer 210 on the first sidewall S1 of the shark-fin-shaped semiconductor structure 218. The thickness T2 of the bottom layer 210 may be greater than the thickness T1 of the bottom layer 210.

Referring back to FIG. 2K, the dashed block 3B may be similar to the dashed block 3A, except for the shark-fin-shaped semiconductor structure 218 close to the semiconductor fin 106a′ and away from the semiconductor fin 106c′. Referring to FIG. 3B, a distance D7 between the bottom portion of the shark-fin-shaped semiconductor structure 218 and the semiconductor fin 106a′ is greater than a distance D8 between the bottom portion of the shark-fin-shaped semiconductor structure 218 and the semiconductor fin 106c′, according to some embodiments.

Since the plasma extends the opening 216 more at smaller pitches, the opening 216 may be deeper between the shark-fin-shaped semiconductor structure 218 and the semiconductor fin 106c′ than between the shark-fin-shaped semiconductor structure 218 and the semiconductor fin 106a′. The opening 216 may have a lower tapered portion 216c and an upper tapered portion 216d over the lower tapered portion 216c. The lower tapered portion 216c may be between the shark-fin-shaped semiconductor structure 218 and the semiconductor fin 106c′. The upper tapered portion 216b may be between the semiconductor fin 106a′ and the semiconductor fin 106c′. The width of the upper tapered portion 216d may decrease toward the substrate 102. The width of the lower tapered portion 216c may decrease toward the substrate 102. In some embodiments, a minimum width of the upper tapered portion 216d may be less than a maximum width of the lower tapered portion 216c.

Then, referring to FIG. 2L, the bottom layer 210 is removed by using an ashing process, according to some embodiments. The ashing process may include an oxygen plasma strip or another suitable technique. The shark-fin-shaped semiconductor structure 218 has self-repair even-odd capability, which can change stress S on adjacent semiconductor fins 106, thereby altering even-odd phenomenon. Consequently, the semiconductor fins 106 may remain substantially vertical to the substrate 102. Afterwards, the pad layer 202 and the hard mask layer 204 may be performed by using a suitable etching process, including a dry etching process, a wet etching process, or a combination thereof.

Then, referring to FIG. 2M, isolation features 104 are formed over the substrate 102 to isolate neighboring semiconductor fins 106, according to some embodiments. The respective process is illustrated as operation 306 in the method 300 as shown in FIG. 6. The isolation features 104 may include shallow trench isolation (STI) features. The isolation features 104 may include a dielectric constant between about 3 and about 5. The isolation features 104 may be formed by depositing a dielectric layer, including SiO₂, silicon nitride, silicon oxynitride, fluorine-doped silicate glass (FSG), a low-k dielectric, another suitable materials, or a combination thereof. The dielectric layer used to form the isolation features 104 may be deposited by CVD, ALD, PVD, or another suitable process. The isolation features 104 may include a multi-layer structure, for example, having one or more liner layers.

Then, a planarization process, such as a chemical mechanical polishing (CMP) process, may be performed to remove excess dielectric layer. According to some other embodiments, the pad layer 202 and the hard mask layer 204 are not removed by the etching process as discussed previously; they are removed by using the CMP process instead. Subsequently, the dielectric layer may be recessed by an etching process, which may include a dry etching process, a wet etching process, or a combination thereof. The etching process may use an etchant with a high etching ratio of dielectric materials to the semiconductor material. The remaining portions of the dielectric layer may form the isolation features 104. Top portions of the semiconductor fins 106 may be exposed, and the shark-fin-shaped semiconductor structure 218 may be covered by the isolation features 104.

After being recessed, the isolation features 104 may have different thickness across the shark-fin-shaped semiconductor structure 218. In particular, a maximum thickness T3 of the isolation features 104 between the semiconductor fin 106a and the shark-fin-shaped semiconductor structure 218 may be greater than a thickness T4 of the isolation features 104 directly above the point P of the shark-fin-shaped semiconductor structure 218. A maximum thickness T5 of the isolation features 104 between the semiconductor fin 106c and the shark-fin-shaped semiconductor structure 218 may be greater than the thickness T4 of the isolation features 104 directly above the point P of the shark-fin-shaped semiconductor structure 218. The maximum thickness T3 of the isolation features 104 between the semiconductor fin 106a and the shark-fin-shaped semiconductor structure 218 may be greater than, substantially equal to, or less than the maximum thickness T5 of the isolation features 104 between the semiconductor fin 106c and the shark-fin-shaped semiconductor structure 218.

Then, as illustrated in FIG. 2N, sacrificial gate structures 220 are formed over the isolation features 104. The sacrificial gate structures 220 may be used as part of a “gate-last” process, where an active gate structure replaces a sacrificial gate structure at a late stage of a semiconductor device fabrication process. The term “active gate” is used to describe a functional gate in finished transistor device. The sacrificial gate structures 220 may be disposed over and across the semiconductor fins 106. The sacrificial gate structures 220 may cover the sidewalls of the semiconductor fins 106 and may be separated from the shark-fin-shaped semiconductor structure 218 by the isolation features 104.

Each of the sacrificial gate structures 220 may include a gate dielectric layer 222 and a sacrificial gate electrode layer 224 over the gate dielectric layer 222. The gate dielectric layer 222 may include an oxide, such as SiO₂. Alternatively, the gate dielectric layer 222 may include a low-k dielectric, such as hafnium oxide (HfO₂), TiO₂, HfZrO, Ta₂O₃, HfSiO₄, ZrO₂, ZrSiO₂, another suitable material, or a combination thereof. The gate dielectric layer 222 may be formed by thermal oxidation, ALD, another suitable method, or a combination thereof. The sacrificial gate electrode layer 224 may include polysilicon or another suitable material. The sacrificial gate electrode layer 224 may be formed by CVD, PVD, ALD, another suitable material, or a combination thereof.

The sacrificial gate structure 220 may be formed by depositing, patterning, and etching processes. The depositing may include the above-mentioned methods. The patterning may include photolithography processes. The photolithography processes may include photoresist coating (e.g., spin-on coating), soft baking, mask aligning, exposure, post-exposure baking, developing the photoresist, rinsing, drying (e.g., hard baking), other suitable processes, and/or combinations thereof. The etching processes may include dry etching, wet etching, or a combination thereof.

Then, the fabrication stage of FIG. 2N is proceeded with FIG. 2O, with the portion indicated by a dashed block 2O in FIG. 2N. Referring to FIG. 2O, sidewall spacers 226 are formed along the sidewalls of the sacrificial gate structure 220. The sidewall spacers 226 may include a dielectric material, such as silicon oxide, silicon nitride, silicon carbide, silicon oxynitride, or a combination thereof. The sidewall spacers 226 may have multiple layers. The sidewall spacers 226 may be formed by depositing a sidewall spacer layer and then anisotropic dry etching the sidewall spacer layer. Afterwards, the portions of the semiconductor fins 106 on opposite sides of the sacrificial gate structure 220 are recessed to form source/drain recesses 228, according to some embodiments.

Subsequently, referring to FIG. 2P, source/drain features 108 are formed in the source/drain recesses 228 by epitaxial growing processes, including chemical vapor deposition (CVD) deposition techniques (e.g., vapor-phase epitaxy (VPE) and/or ultra-high vacuum CVD (UHV-CVD)), molecular beam epitaxy, another suitable processes, or a combination thereof. The source/drain features 108 may include a strained material. For example, the source/drain features 108 may include Ge, Si, GaAs, aluminum gallium arsenide (AlGaAs), SiGe, gallium arsenide phosphide (GaAsP), GaSb, InSb, indium gallium arsenide (InGaAs), InAs, another suitable materials, or a combination thereof. A lattice constant of the strained material may be different from a lattice constant of the semiconductor fins 106. Accordingly, the source/drain features 108 may serve as a stressor that improves carrier mobility.

After the source/drain recesses 228 are filled with the materials of the source/drain features 108, an epitaxial growth of a top layer of the source/drain features 108 may expand horizontally and facets may start to form, such as a diamond shape facets. A height of the source/drain features 108 may be greater than a height of the semiconductor fins 106. The source/drain features 108 may be in-situ doped during the epitaxial processes. Alternatively, an implantation process (such as a junction implant process) may be performed to dope the source/drain features 108 after the epitaxial processes. One or more annealing processes may be performed to activate dopants. The annealing processes may include rapid thermal annealing (RTA), laser annealing processes, or another suitable technique.

In some embodiments, a dielectric structure (not shown) may be formed over the substrate 102 and covering the sacrificial gate structure 220 and the source/drain features 108. The dielectric structure may include a contact etch-stop layer (CESL) and an interlayer dielectric (ILD). In some embodiments, the CESL may include silicon nitride SiN, SiCN, SiOCN, SiOC, and/or other applicable materials. In some embodiments, the ILD may include multilayers made of multiple dielectric materials, such as silicon oxide, silicon nitride, silicon oxynitride, tetraethoxysilane (TEOS), phosphosilicate glass (PSG), borophosphosilicate glass (BPSG), low-k dielectric material, and/or other applicable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), and polyimide.

In some embodiments, referring to FIG. 2Q, a gate isolation feature 230 is formed over the isolation features 104 and between the sacrificial gate structure 220. The gate isolation feature 230 may be formed by depositing dielectric materials, including silicon oxide, silicon nitride, oxynitride, or another suitable dielectric materials. Next, a polishing process (e.g. a CMP operation) may be performed on the gate isolation feature 230 to expose top surfaces of the sacrificial gate structure 220. The gate isolation feature 230 may serve to electrically isolate gate metal lines of neighboring gate structures. The isolation feature 230 may have a non-planar bottom surface. The isolation feature 230 may be across some of the shark-fin-shaped semiconductor structures 218.

Then, the sacrificial gate structures 220 are replaced by gate structures 110, according to some embodiments. The sacrificial gate structures 220 may be removed to form gate trenches (not illustrated). In some embodiments, the gate dielectric layer 222 is removed for forming an interfacial layer (IL). In some other embodiments, the gate dielectric layer 222 may be left in the gate trench. It should be noted that the removal of the gate dielectric layer 222 may be performed depending on different process or product requirements. The semiconductor fins 106 may be exposed through the gate trenches.

Afterwards, gate structures 110 are formed in the gate trenches, according to some embodiments. The respective process is illustrated as operation 308 in the method 300 as shown in FIG. 6. The gate structures 110 may interface the top surface of the isolation feature 104. Forming of the gate structures 110 may include further operations. In some embodiments, a gate dielectric layer 112 is formed in the gate trenches. The gate dielectric layer 112 and the isolation feature 104 may intermix at an interface between the gate dielectric layer 112 and the isolation feature 104. In some embodiments, an IL layer is formed prior to forming the gate dielectric layer 112, though not shown. The IL layer may include an oxide-containing material such as SiO or SiON. In some embodiments, the IL layer covers portions of the semiconductor fins 106 exposed in the gate trenches.

The gate dielectric layer 112 may be conformally formed in the gate trenches. Accordingly, the gate dielectric layer 112 may cover at least sidewalls of the gate trenches. In some embodiments, the gate dielectric layers 262 includes a high-k dielectric material having a high dielectric constant, for example, greater than that of thermal silicon oxide (~3.9). The high-k dielectric material may include hafnium oxide (HfO₂), zirconium oxide (ZrO₂), lanthanum oxide (La₂O₃), aluminum oxide (Al₂O₃), titanium oxide (TiO₂), yttrium oxide (Y₂O₃), strontium titanate (SrTiO₃), hafnium oxynitride (HfOxNy), another suitable metal-oxide, or a combination thereof.

The gate electrode 114 may include a multilayer structure, including at least one work function metal layer and a gap-filling metal layer. The work function metal layer may include n-type or p-type work function metal materials, depending on the product design. Further, the work function metal layer may be a single-layered structure or multilayers of two or more materials, but the disclosure is not limited thereto. In some embodiments, a gap-filling metal layer is formed to fill the gate trenches. In some embodiments, the gap-filling metal layer may include conductive material such as Al, Cu, AlCu or W, but is not limited to the above-mentioned materials. Accordingly, the gate structure 110 is referred to as a metal gate structure.

The gate structures 110 may have non-planar bottom surfaces, and the isolation feature 104 may have non-planar top surfaces. Each of the gate structure 110 may be across two of the semiconductor fins 106 and one shark-fin-shaped semiconductor structure 218 as illustrated, but the present disclosure is not limited thereto. The gate structure 110 may be across one or more than two semiconductor fins 106 and more than one shark-fin-shaped semiconductor structure 218. The gate structure 110 may cover the sidewalls of the semiconductor fins 106 and may be separated from the shark-fin-shaped semiconductor structure 218 by the isolation feature 104.

The gate isolation feature 230 may be between two gate structures, and may include a first portion over the isolation feature 104 and a second portion extending into the isolation feature 104. Although the gate isolation feature 230 is formed before forming the gate structures 110 in the previous discussion, the present disclosure is not limited thereto. In some other embodiments, the gate isolation feature 230 is formed through the gate structures 110 after forming the gate structures 110.

Then, referring to FIG. 2R, a dielectric layer 232 is formed over the gate structures 110, according to some embodiments. The dielectric layer 232 may include an etch stop layer and another inter-layer dielectric (ILD) structure over the etch stop layer. The etch stop layer may include silicon nitride, silicon oxynitride, or another suitable material. The ILD structure may include multilayers made of multiple dielectric materials, such as silicon oxide, silicon nitride, silicon oxynitride, tetraethoxysilane (TEOS), phosphosilicate glass (PSG), borophosphosilicate glass (BPSG), low-k dielectric material, and/or another suitable dielectric material. Examples of low-k dielectric materials may include fluorinated silica glass (FSG), carbon-doped silicon oxide, amorphous fluorinated carbon, parylene, bis-benzocyclobutenes (BCB), polyimide, or another suitable material.

Afterwards, conductive features 234 are formed through the dielectric layer 232, using, for example middle-end-of-line (MEOL) operations, according to some embodiments. The semiconductor structure 100 is thus formed. The conductive features 234 may be referred to as contacts, plugs, or the like. The conductive features 234 may include a tungsten (W) layer. Alternatively, the conductive features 234 may include other conductive materials, such as metals, including Ni, Pd, Pt, Be, Ir, Te, Re, Ru, Rh, W, Mo, WN, RuN, MoN, TiN, TaN, WC, TaC, TiC, TiAlN, TaAlN, or a combination thereof. The conductive features 234 may be a multilayer structure, for example, including an adhesion layer, a barrier layer over the adhesion layer, and a conductive material over the barrier layer. After sequentially depositing the adhesion layer, the barrier layer, and the conductive material, a planarization process, such as a CMP, may be performed to remove excess conductive material, barrier layer, and adhesion layer from above a top surface of the dielectric layer 232. Hence, the top surfaces of the conductive features 234 may be substantially aligned with the top surface of the dielectric layer 232.

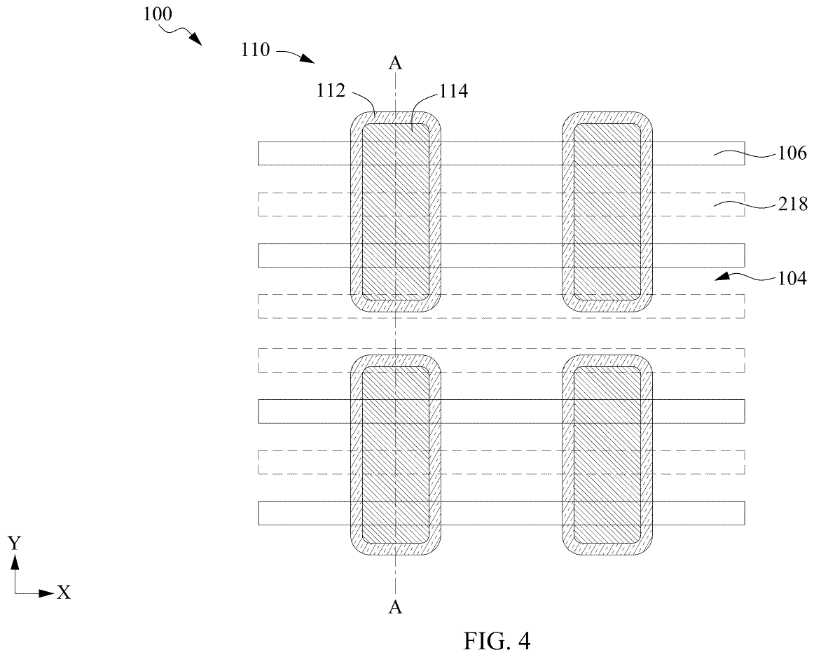

FIG. 4 is a top view illustrating the semiconductor structure 100 according to some embodiments of the present disclosure. FIGS. 2A to 2N, 2Q and 2R are cross-sectional views taken along the A-A line in FIG. 4. As illustrated in FIG. 4, the semiconductor fins 106 may extend in the X direction, and the gate structure 110 may extend in the Y direction. The gate structure 110 may be across two semiconductor fins 106 and one shark-fin-shaped semiconductor structure 218.

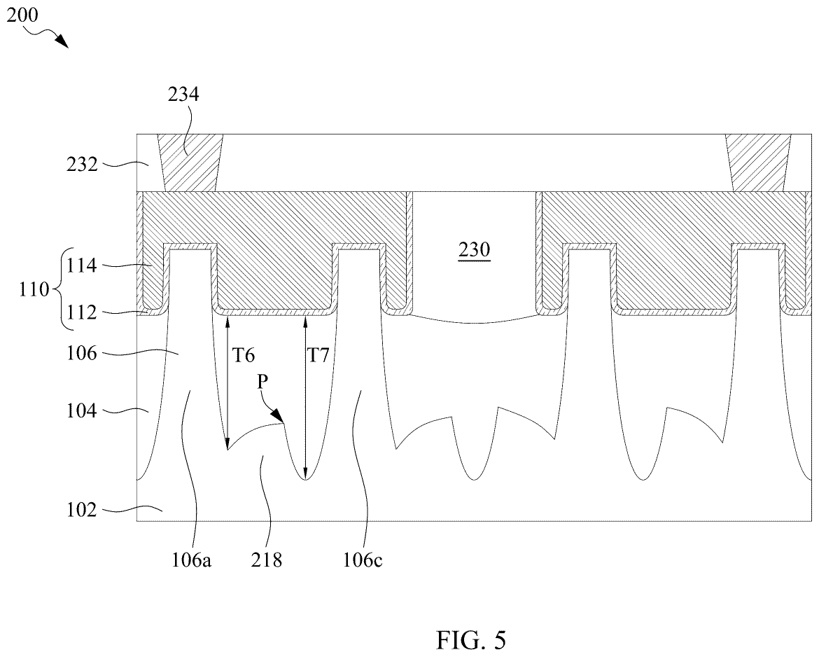

FIG. 5 is a cross-sectional view illustrating a semiconductor structure 200 according to some other embodiments of the present disclosure. Some components of the semiconductor structure 200 may be similar to those of the semiconductor structure 100 as described with reference to FIG. 2R, and will not be repeated.

As illustrated in FIG. 5, the bottom surfaces of the isolation features 104 may have height difference due to smaller pitches between the semiconductor fins 106 or adjustment of plasma parameters. As a result, a bottom surface of the isolation features 104 between the semiconductor fin 106a and the shark-fin-shaped semiconductor structure 218 may be higher than a bottom surface of the isolation features 104 between the semiconductor fin 106c and the shark-fin-shaped semiconductor structure 218. In addition, a maximum thickness T6 of the isolation features 104 between the semiconductor fin 106a and the shark-fin-shaped semiconductor structure 218 may be different from a thickness T7 of the isolation features 104 between the semiconductor fin 106c and the shark-fin-shaped semiconductor structure 218. In some embodiments, the maximum thickness T6 of the isolation features 104 between the semiconductor fin 106a and the shark-fin-shaped semiconductor structure 218 may be less than the thickness T7 of the isolation features 104 between the semiconductor fin 106c and the shark-fin-shaped semiconductor structure 218.

In summary, the present disclosure provides a method for forming a semiconductor structure. The method may include removing unnecessary semiconductor fins by using a high power plasma. A shark-fin-shaped semiconductor structure may thus be formed, which has self-repair even-odd capability to change stress on adjacent semiconductor fins, thereby addressing issues with poor metal gate filling.

Some embodiments of the present disclosure provide a semiconductor structure. The semiconductor structure includes a substrate, a first semiconductor fin, a shark-fin-shaped semiconductor structure, a second semiconductor fin, an isolation feature, and a gate structure. The first semiconductor fin, the shark-fin-shaped semiconductor structure, and the second semiconductor fin extend over the substrate. The isolation feature is disposed over the substrate and between the first semiconductor fin and the second semiconductor fin and is adjacent to a sidewall of the first semiconductor fin. The gate structure extends over the isolation feature, the first semiconductor fin, the shark-fin-shaped semiconductor structure, and the second semiconductor fin and interfaces a top surface of the isolation feature. The gate structure includes a gate dielectric layer and at least one metal layer over the gate dielectric layer. The gate dielectric layer and the isolation feature intermix at an interface between the gate dielectric layer and the isolation feature. The shark-fin-shaped semiconductor structure has a first sidewall and a second sidewall connected to the first sidewall at a point.

Some embodiments of the present disclosure provide a method for forming a semiconductor structure. The method includes forming a first semiconductor fin, a second semiconductor fin, and a third semiconductor fin over a substrate and extending lengthwise along a direction. The method also includes partially removing the second semiconductor fin by using a plasma and remaining a tapered root portion of the second semiconductor fin. The method also includes forming an isolation feature over the substrate and between the first semiconductor fin and the third semiconductor fin. The method also includes forming a gate structure over the first semiconductor fin and extending along surfaces of a portion of the first semiconductor fin and the top surface of the isolation feature. The gate structure includes a gate dielectric layer and at least one metal layer over the gate dielectric layer. The gate dielectric layer and the isolation feature intermix at an interface between the gate dielectric layer and the isolation feature.

Some embodiments of the present disclosure provide a method for forming a semiconductor structure. The method includes forming a first semiconductor fin, a second semiconductor fin, and a third semiconductor fin over a substrate. The method also includes partially etching the second semiconductor fin by using a plasma to form a shark-fin-shaped semiconductor structure. The method also includes forming an isolation feature over the substrate and between the first semiconductor fin and the third semiconductor fin along a direction. The method also includes forming a gate isolation feature over the isolation feature and between the first semiconductor fin and the third semiconductor fin. The method also includes forming a first gate structure over the first semiconductor fin and interfacing a top surface of the isolation feature. The method also includes forming a second gate structure over the third semiconductor fin. The gate isolation feature is between the first gate structure and the second gate structure along the direction. The gate isolation feature includes a first portion over the isolation feature and a second portion extending into the isolation feature.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a substrate;
a first semiconductor fin, a shark-fin-shaped semiconductor structure, and a second semiconductor fin extending over the substrate;
an isolation feature disposed over the substrate and between the first semiconductor fin and the second semiconductor fin and adjacent to a sidewall of the first semiconductor fin;
a gate structure extending over the isolation feature, the first semiconductor fin, the shark-fin-shaped semiconductor structure, and the second semiconductor fin and interfacing a top surface of the isolation feature, wherein the gate structure comprises a gate dielectric layer and at least one metal layer over the gate dielectric layer, wherein the gate dielectric layer and the isolation feature intermix at an interface between the gate dielectric layer and the isolation feature,
wherein the shark-fin-shaped semiconductor structure has a first sidewall and a second sidewall connected to the first sidewall at a point.

2. The semiconductor structure of claim 1, wherein the gate structure is separated from the shark-fin-shaped semiconductor structure by the isolation feature.

3. The semiconductor structure of claim 1, wherein a distance between the point and the first semiconductor fin is greater than a distance between the point and the second semiconductor fin.

4. The semiconductor structure of claim 1, wherein a minimum distance between the first sidewall and the first fin is less and a minimum distance between second sidewall and the second fin.

5. The semiconductor structure of claim 1, wherein a first included angle between the first sidewall and the substrate is different from a second included angle between the second sidewall and the substrate.

6. The semiconductor structure of claim 1, wherein the shark-fin-shaped semiconductor structure is surrounded by the isolation feature.

7. A method for forming a semiconductor structure, comprising:
forming a first semiconductor fin, a second semiconductor fin, and a third semiconductor fin over a substrate and extending lengthwise along a direction;
partially removing the second semiconductor fin by using a plasma and remaining a tapered root portion of the second semiconductor fin;
forming an isolation feature over the substrate and between the first semiconductor fin and the third semiconductor fin; and
forming a gate structure over the first semiconductor fin and extending along surfaces of a portion of the first semiconductor fin and the top surface of the isolation feature, wherein the gate structure comprises a gate dielectric layer and at least one metal layer over the gate dielectric layer, and the gate dielectric layer and the isolation feature intermix at an interface between the gate dielectric layer and the isolation feature.

8. The method of claim 7, further comprising:
forming a mask layer covering the first semiconductor fin, the second semiconductor fin and the third semiconductor fin;
partially removing the mask layer and second semiconductor fin by using the plasma; and
removing the remaining mask layer before forming the isolation feature.

9. The method of claim 8, further comprising forming an opening in the mask layer, wherein the opening extends from between the first semiconductor fin and the third semiconductor fin to between the first semiconductor fin and the second semiconductor fin.

10. The method of claim 9, wherein the opening has a tapered lower portion between the first semiconductor fin and the second semiconductor fin and a tapered upper portion between the first semiconductor fin and the third semiconductor fin.

11. The method of claim 7, wherein the tapered root portion of the second semiconductor fin has a first sidewall and a second sidewall, and the first sidewall is convex.

12. The method of claim 11, wherein the first sidewall is connected to the second sidewall at a point.

13. The method of claim 12, wherein the isolation feature has different thickness on opposite sides of the point of the tapered root portion of the second semiconductor fin.

14. The method of claim 11, wherein the first sidewall extends from a bottom portion of the first semiconductor fin toward a middle portion of the third semiconductor fin.

15. The method of claim 7, wherein a distance between a top surface of the third semiconductor fin and a top surface of the second semiconductor fin is greater than a distance between a top surface of the first semiconductor fin and the top surface of the second semiconductor fin.

16. A method for forming a semiconductor structure, comprising:
forming a first semiconductor fin, a second semiconductor fin, and a third semiconductor fin over a substrate;
partially etching the second semiconductor fin by using a plasma to form a shark-fin-shaped semiconductor structure;
forming an isolation feature over the substrate and between the first semiconductor fin and the third semiconductor fin along a direction;
forming a gate isolation feature over the isolation feature and between the first semiconductor fin and the third semiconductor fin;
forming a first gate structure over the first semiconductor fin and interfacing a top surface of the isolation feature; and
forming a second gate structure over the third semiconductor fin, wherein the gate isolation feature is between the first gate structure and the second gate structure along the direction, and the gate isolation feature includes a first portion over the isolation feature and a second portion extending into the isolation feature.

17. The method of claim 16, further comprising:
forming a first hard mask, a second hard mask, and a third hard mask over the first semiconductor fin, the second semiconductor fin, and the third semiconductor fin, respectively;
forming a mask layer covering the first hard mask, the second hard mask, and the third hard mask;
forming an opening in the mask layer to expose the second hard mask;
removing the second hard mask and a top portion of the second semiconductor fin;
removing a middle portion of the second semiconductor fin and remaining the shark-fin-shaped semiconductor structure; and
removing the mask layer.

18. The method of claim 17, wherein the opening is deepened when removing the middle portion of the second semiconductor fin.

19. The method of claim 16, further comprising forming additional shark-fin-shaped semiconductor structure below the gate isolation feature by using the plasma.

20. The method of claim 16, wherein the first gate structure is across and separated from the shark-fin-shaped semiconductor structure.
